(19) United States
(12) Patent Application Publication
(10) Pub. No.: US 2013/0141125 A1
(43) Pub. Date: Jun. 6, 2013

(54) DEVICE AND METHOD FOR TESTING STABLITY OF ELECTRONIC DEVICES

(71) Applicant: SEN-FENG CHANG, Tu-Cheng (TW)

(72) Inventor: SEN-FENG CHANG, Tu-Cheng (TW)

(73) Assignee: HON HAI PRECISION INDUSTRY CO., LTD., Tu-Cheng (TW)

(21) Appl. No.: 13/494,034

(22) Filed: Jun. 12, 2012

(30) Foreign Application Priority Data
Dec. 5, 2011 (TW) 100144559

(51) Int. Cl. G01R 31/00

(52) U.S. Cl. 324/750.01

(57) ABSTRACT

A test device is connected to a plurality of electronic devices to test a stability of the electronic devices is provided. The test device includes a parameter setting module, a signal generating module, a communication module, and a monitoring module. The parameter setting module sets test parameters for a test in response to a user input. The signal generating module generates a control signal according to the test parameters set by the user to control the electronic devices to execute operations corresponding to the test parameters. The communication module transmits the control signal to the electronic devices. The monitoring module monitors whether the electronic devices are running in a normal state during the test to determine the stability of the electronic devices and further informs the monitoring result to the user.

### BACKGROUND

1. Technical Field

The present disclosure relates to test devices, and particularly, to a device and a method for testing stability of electronic devices.

2. Description of Related Art

Stability testing may be performed during the manufacturing process of a server. For example, to test the stability of the power of a server, a test device may be connected to the server and monitors whether the server is abnormal when the server is repeatedly started and shut down for several times. However, the test device only can test one server each time.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure.

Moreover, in the drawings, like reference numerals designate corresponding portions throughout the several views.

FIG. 1 is a block diagram of a test device in accordance with an exemplary embodiment.

FIG. 2 is a flowchart of a test method in accordance with an exemplary embodiment.

### DETAILED DESCRIPTION

Embodiments of the present disclosure will now be described in detail, with reference to the accompanying drawings.

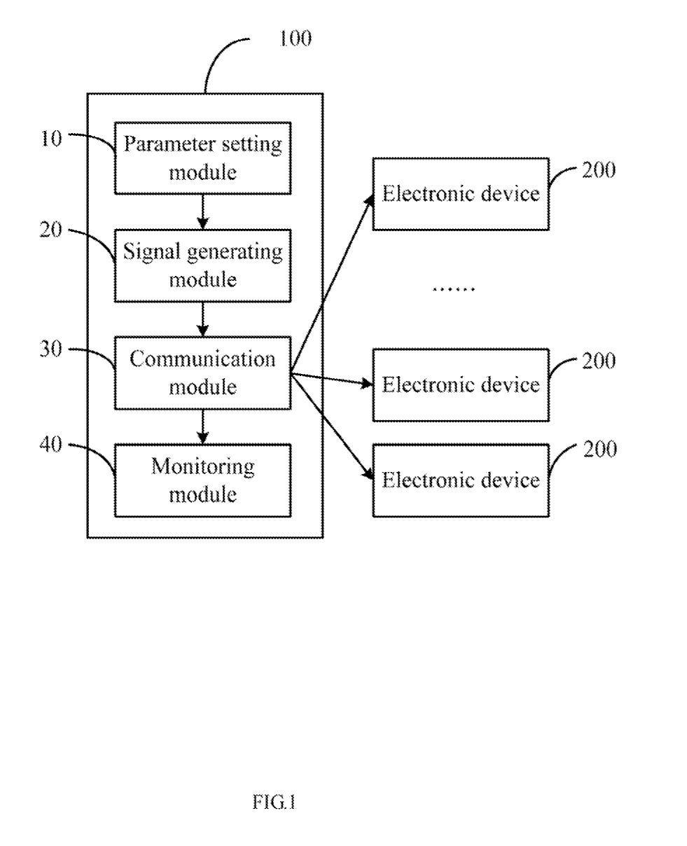

Referring to FIG. 1, an embodiment of a test device 100 is connected to a plurality of electronic devices 200 to test the stability of the electronic devices 200 at the same time and outputs a test result to an operator. In the embodiment, the electronic devices 200 are servers contained in a data center. The test device 100 is used to test the stability of the powers of the servers 200 by monitoring whether the servers 200 are running in a normal state when the servers are continuously start/shut down for hundreds of times. In the embodiment, each of the electronic devices 200 has a unique identifier.

The test device 100 includes a parameter setting module 10, a signal generating module 20, a communication module 30, and a monitoring module 40.

The parameter setting module 10 sets test parameters in response to a user input.

In the embodiment, the test parameters include the total times that the electronic devices 200 are to be started/shut down in the test, and the time interval between two times the electronic devices 200 are started/shut down. For example, the parameter setting module 10 may set the servers 200 to start/shut down for 1000 times in the test, and the time interval between two times start/shut down is 2 seconds. In the embodiment, the parameter setting module 10 sets a test parameter for all the electronic devices 200 at the same time in response to user's input. In an alternative embodiment, the parameter setting module 10 may set different test parameters for different electronic devices 200. In other embodiments, the test parameters may include the items to be tested, such as the software/hardware of the electronic device 200, the test content, such as the voltage and the temperature of the electronic device 200, and the time interval of the test.

The signal generating module 20 generates a control signal according to the test parameters set by the user to control the electronic devices 200 to execute operations corresponding to the test parameters. In the embodiment, the signal generating module 20 generates controls signals to control the electronic devices 200 to execute the start/shut down operations according to the parameter set by the user.

The communication module 30 communicates with each of the electronic devices 200 and transmits the control signals to each electronic device 200. In the embodiment, the control signal generated by the signal generating module 20 can be read by an application running in the electronic devices 200, and the application controls the electronic devices 200 to execute the start and shut down operation continuously for the set total times according to the control signal. In an alternative embodiment, the control signal can be read by a Baseboard Management Controller (BMC) contained in the electronic devices 200, the BMC controls the electronic device 200 to execute the start and shut down operation continuously for the set total times according to the control signal.

The monitoring module 40 monitors whether the electronic devices 200 are running in a normal state during the test and outputs the monitor result to the user. In detail, if any of the electronic devices 200 is abnormal during the test, the monitoring module 40 determines the electronic device 200 is unstable and generates a warning to inform the user that the electronic device 200 is abnormal. In the embodiment, the term abnormal means that the electronic device 200 cannot be started or cannot be shut down. If the electronic device 200 is running in a normal state during the whole test, the monitoring module 40 determines the electronic device 200 is stable and generates a notification to inform the user that the electronic device 200 is stable.

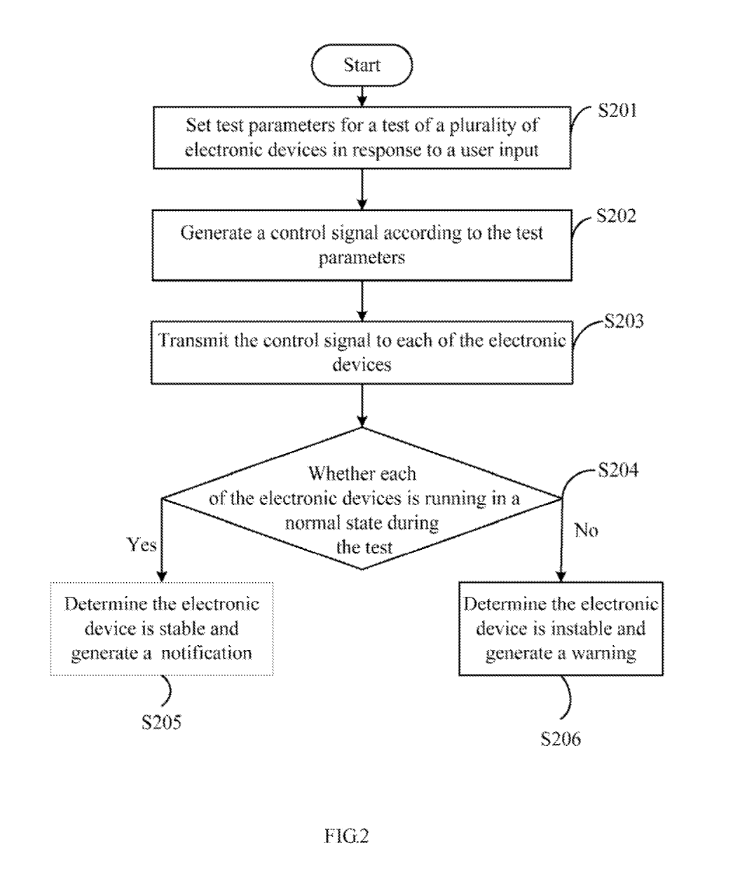

FIG. 2 is a flowchart of a test method in accordance with an exemplary embodiment.

In step S201, the parameter setting module 10 sets test parameters in response to a user input. In the embodiment, the test parameters include the total times that the electronic devices 200 are to be started/shut down in the test, and the time interval between two times the electronic devices 200 are started/shut down. In other embodiments, the test parameters may include the items to be test, such as the software/hardware of the electronic device 200, the test content, such as the voltage and the temperature of the electronic device 200, and the time interval of the test.

In step S202, the signal generating module 20 generates a control signal according to the test parameters set by the user to control the electronic devices 200 to execute operations corresponding to the test parameters.

In step S203, the communication module 30 transmits the control signals to each of the electronic devices 200.

In step S204, the monitoring module 40 monitors whether the electronic devices 200 are running in a normal state during the test, if yes, the procedure goes to step S205, otherwise, the procedure goes to step S206. In the embodiment, the monitoring module 40 monitors whether the electronic devices 200 are running in a normal state by monitoring whether the electronic device 200 starts/shut down in a normal state during the test.

In step S205, the monitoring module 40 determines that the electronic device 200 is stable and generates a notification to inform the user that the electronic device 200 is stable.

In step S206, the monitoring module 40 determines that the electronic device 200 is unstable and generates a warning to inform the user that the electronic device is abnormal.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A test device connected to a plurality of electronic devices to test a stability of the electronic devices, comprising:
a parameter setting module to set test parameters for a test in response to a user input;
a signal generating module to generate a control signal according to the test parameters to control the electronic devices to execute operations corresponding to the test parameters;
a communication module to transmit the control signal to the electronic devices; and
a monitoring module to monitor whether the electronic devices are running in a normal state during the test to determine the stability of the electronic devices and to output a monitor result to the user.

2. The test device as described in claim 1, wherein the parameter setting module sets same test parameters for all the electronic devices at the same time.

3. The test device as described in claim 1, wherein the parameter setting module sets different test parameters for different electronic devices in response to the user input.

4. The test device as described in claim 1, wherein the test parameters set by the user comprise total times that the electronic devices to be started/shut down in the test, and a time interval between two times the electronic devices to be started/shut down.

5. The test device as described in claim 4, wherein the monitoring module determines that a stability of a first one of the electronic devices is stable and generating a notification to inform the user that the electronic device is stable if the first one of the electronic devices is running in a normal state during the whole test; and determines that a stability of a second one of the electronic device is unstable and generating a warning to warn the user that the electronic device is unstable if the second one of the electronic devices is abnormal during the test.

6. A test method for testing the stability of a plurality of electronic devices at the same time, comprising:
setting test parameters for a test of a plurality of electronic devices in response to a user input;
generating a control signal according to the test parameters;
transmitting the control signals to each of the electronic devices to control the electronic devices to execute operations corresponding to the test parameters;
monitoring whether each of the electronic devices is running in a normal state during the test; and
informing the monitoring result to the user.

7. The test method as described in claim 6, wherein informing the monitoring result comprising:
determining that a stability of a first one of the electronic devices is stable and generating a notification to inform the user that the electronic device is stable if the first one of the electronic devices is running in a normal state during the whole test; and
determining that a stability of a second one of the electronic device is unstable and generating a warning to warn the user that the electronic device is unstable if the second one of the electronic devices is abnormal during the test.

8. The test method as described in claim 7, wherein the test parameters include total times that the electronic devices to be started/shut down in the test, and a time interval between two times the electronic devices to be started/shut down.
